(19) United States
(12) Patent Application Publication
(10) Pub. No.: US 2026/0059669 A1
(43) Pub. Date: Feb. 26, 2026

(54) MEMORY SYSTEM INCLUDING INTERLEAVED MEMORY CHANNELS

(71) Applicant: Advanced Micro Devices, Inc., Santa Clara, CA (US)

(72) Inventors: David Da-Wei LIN, Westborough, MA (US); Anwar KASHEM, Boxborough, MA (US)

(21) Appl. No.: 18/813,825

(22) Filed: Aug. 23, 2024

(51) Int. Cl. H05K 1/18

(52) U.S. Cl. CPC H05K 1/184; H05K 2201/10159; H05K 2201/10303

(57) ABSTRACT

A memory system includes a host circuitry coupled to a memory circuitry, the host circuitry including a first set of memory channels comprising first memory channels and second memory channels that are interleaved with one another, and a second set of memory channels comprising third memory channels and fourth memory channels that are interleaved with one another.

### TECHNICAL FIELD

An embodiment relates to memory systems. More particularly, an embodiment relates to an architecture for a memory system that includes interleaved memory channels.

### BACKGROUND

A computing system may employ many different types of semiconductor memory devices communicating with a host through different types of buses. These memory devices may include volatile as well as non-volatile memories. In one or more examples, the memory devices may include double data rate (DDR) synchronous dynamic random access memory (SDRAM).

DDR SDRAM allows data to be transferred from the memory devices to the host on both the rising and falling edges of a clock signal. The memory devices are usually implemented using some type of dynamic random access memory (DRAM). Some examples of DRAM types include synchronous DRAM (SDRAM) as well as the various types of DDR SDRAM.

As the quantity of memory channels (i.e., DDR channels) of memory devices increases, routing traces between a host and a memory device becomes increasingly complex, resulting in long and crowded traces between the host and the memory circuitry. The long and crowded traces could lead to severe insertion loss, return loss, and cross talk, which degrade the performance of the overall device.

### SUMMARY

According to one or more examples, a memory system includes a printed circuit board (PCB); a memory circuitry mounted to the PCB includes a first memory device comprising a first set of memory chips and a first set of memory pins including first memory pins coupled to the first set of memory chips, and a second memory device including a second set of memory chips and a second set of memory pins including second memory pins coupled to the second set of memory chips, wherein the first set of memory pins and the second set of memory pins are mounted to corresponding pins of the PCB, and a host circuitry mounted to the PCB and coupled to the memory circuitry, the host circuitry including a first set of memory channels comprising first memory channels and second memory channels that are interleaved with one another, a first set of host pins comprising first host pins that are coupled to the first memory channels and second host pins that are coupled to the second memory channels, and first memory traces formed in a first layer of a fan-out package, the first memory traces coupling the first host pins to the first memory pins and the second host pins to the second memory pins.

According to one or more examples, a memory system includes a host circuitry coupled to a memory circuitry, the host circuitry including a first set of memory channels comprising first memory channels and second memory channels that are interleaved with one another, and a second set of memory channels comprising third memory channels and fourth memory channels that are interleaved with one another.

According to one or more examples, a memory system includes a host circuitry coupled to a memory circuitry, the host circuitry including a first set of memory channels comprising first memory channels, second memory channels, a third memory channel, and a fourth memory channel that are interleaved with one another, and a second set of memory channels comprising third memory channels, fourth memory channels, a fifth memory channel, and a sixth memory channel that are interleaved with one another.

### BRIEF DESCRIPTION OF DRAWINGS

FIG. 1 illustrates a schematic diagram of a memory system according to one or more examples.

FIG. 2A illustrates an abstract schematic view of the memory system in the x-z plane, according to one or more examples.

FIG. 2B illustrates an abstract schematic view of a first layer of a fan-out package of the memory system in the x-y plane according to one or more examples.

FIG. 2C illustrates an abstract schematic view of a second layer of a fan-out package of the memory system in the x-y plane according to one or more examples.

FIG. 3 illustrates an abstract schematic view of a host IC of the memory system in the x-y plane according to one or more examples.

FIG. 4 illustrates a flow diagram of a method 400 for forming a memory system.

### DETAILED DESCRIPTION

As the quantity of memory channels, such as DDR channels, implemented on a memory device of a computing device increase, routing traces between a host and a memory device becomes increasingly complex. Routing traces are the bottleneck of modern high speed computing devices. As the number of memory channels increases, long, narrow, and crowded crossing traces are required to couple the memory channels to the host. The long, narrow, and crowded traces could lead to severe insertion loss, return loss, and cross talk, which will eventually degrade the performance of the overall device. Conventionally, to combat this, additional layers of traces is added to the fan-out-package of the host circuitry. However, the increase in the number of layers of increases the manufacturing cost and size of the host.

Embodiments herein relate to interleaving different sets of memory channels within a host in a same column so that traces between the memory device and the host are shorter, avoid cross-talk, and reduce the number of layers of traces required in the fan-out package of the host.

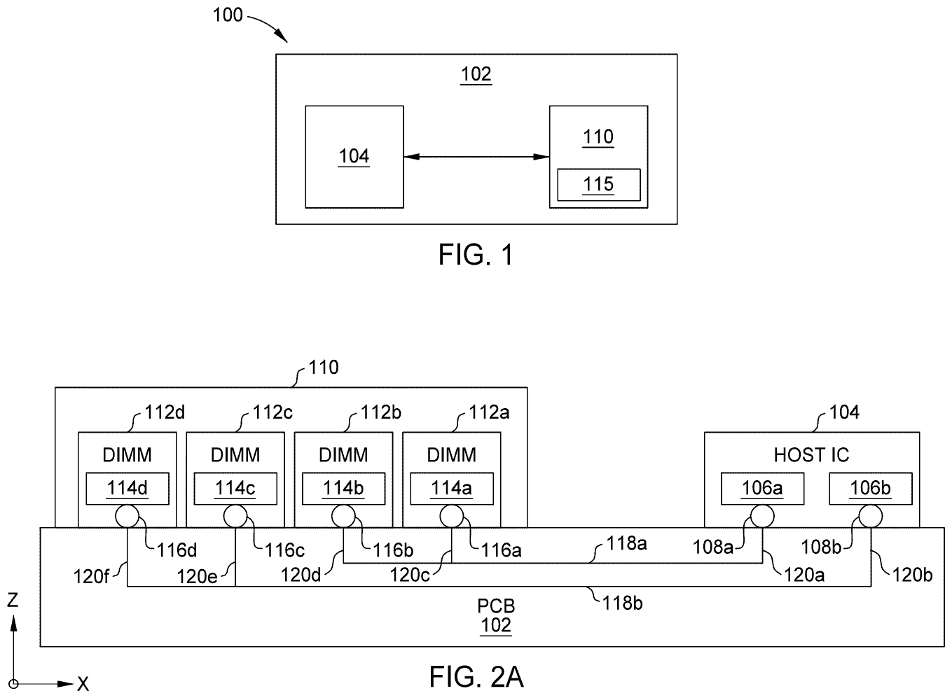

FIG. 1 illustrates a schematic diagram of a memory system 100 according to one or more examples. The memory system 100 may be included in any system that includes a memory interface such as a desktop computer, laptop, tablet, video gaming unit or console, a machine-to-machine (M2M) communication system, or the like. In one or more examples, the memory system 100 includes host circuitry 104 coupled to a memory circuitry 110 that are mounted on a substrate, such as a printed circuit board (PCB) 102. In one or more examples, the PCB 102 is a substrate that includes multiple metal layers interleaved with a dielectric material, and the traces are formed within the metal layers. The memory circuitry 110 receives a command from the host circuitry 104 and performs a memory operation based on the command from the host circuitry 104. The memory circuitry 110 writes data provided by the host circuitry 104 to the memory circuitry 110 upon receiving a write command from the host circuitry 104. The memory circuitry 110 reads data to the host circuitry 104 from the memory circuitry 110 upon receiving a read command from the host circuitry 104. The memory circuitry 110 writes data and reads data from one of a plurality of memory chips included in the memory circuitry 110 based on an address provided in the write/read command from the host circuitry 104.

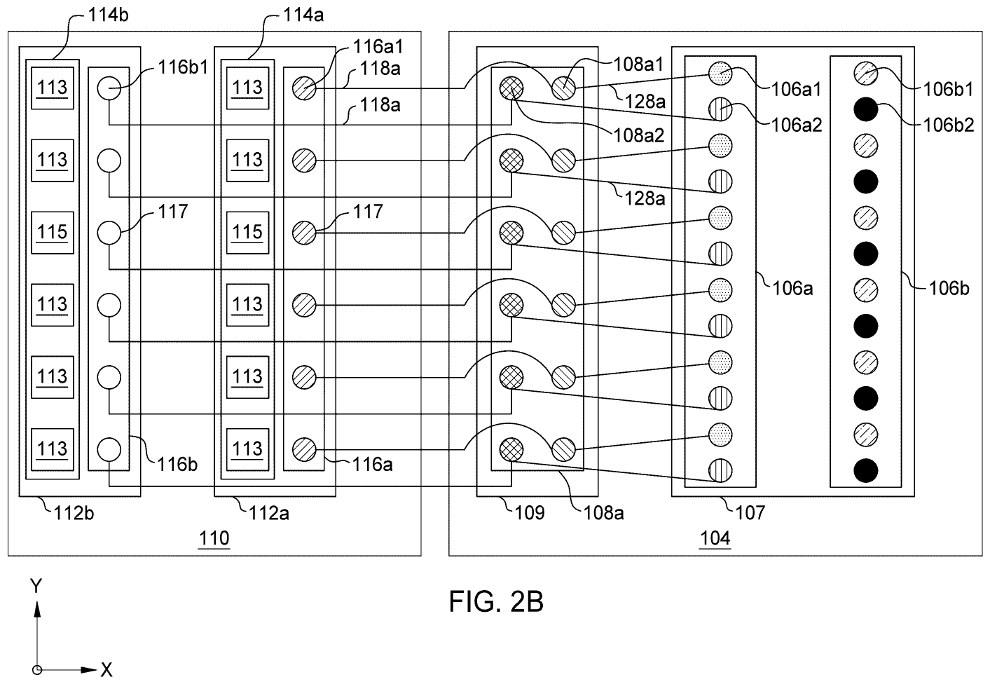

In one or more examples, the memory circuitry 110 is a dynamic random access memory (DRAM), a synchronous random access memory (SDRAM) a static random access memory (SRAM) or the like. The memory circuitry 110 includes at least one memory device that further include at least one memory chip. The quantity of memory devices in the memory circuitry 110 are not limited, and any suitable quantity of memory devices may be included in the memory circuitry 110. For example, the memory circuitry 110 includes at least one memory device such as dual in-line memory module (DIMM) circuitry that includes multiple double data rate (DDR) chips (i.e., memory chips). In one or more examples, each of the memory devices also include a registered clock driver circuitry (RCD) 115 (FIGS. 2B-2C). Each of the DDR chips and the RCD circuitry 115 are coupled to a corresponding DDR channel (i.e., memory channel) included in the host circuitry 104. This will be shown in more detail below.

In one or more examples, the host circuitry 104 may include a host integrated circuitry (host IC) 107. The host IC 107 may issue or generate signals (i.e., commands) for the memory circuitry 110. For example, the host circuitry 104, using the host IC 107, e.g., a central processing unit (CPU) or any other suitable processing unit, may generate a command signal. The command signal may include data to be written into memory devices along with a write command or a command indicating a read operation to be performed by a memory chip in the memory circuitry 110.

FIG. 2A illustrates an abstract schematic view of the memory system 100 in the x-z plane. FIG. 2B illustrates an abstract schematic view of a first layer of a fan-out-package 109 of the host circuitry 104 of the memory system 100 in the x-y plane, according to one or more examples. FIG. 2C illustrates an abstract schematic view of a second layer of a fan-out-package 109 of the host circuitry 104 of the memory system 100 in the x-y plane according to one or more examples.

As noted above, modern memory systems use multiple sets of memory channels that are each coupled to at least one corresponding memory device. In one example, the memory system 100 includes four memory devices coupled to four sets of memory channels. Even though four memory devices coupled to four sets of memory channels are described herein, this is for example purposes only. Any suitable quantity of memory devices and memory channels may be used.

Referring the FIG. 2A, the memory system 100 includes the host circuitry 104 and the memory circuitry 110. In one or more examples, the host circuitry 104 includes a first set of memory channels 106a and a second set of memory channels 106b disposed in a host integrated circuitry (host IC) 107 (FIG. 2B). The first set of memory channels 106a includes two sets of memory channels interleaved with one another. The second set of memory channels 106b includes the other two sets of memory channels interleaved with one another. For example, the first set of memory channels 106a includes first memory channels 106a1 and second memory channels 106a2 (FIG. 2B). The first memory channels 106a1 and the second memory channels 106a2 are interleaved in a single column formed on the host IC 107 (FIG. 2B). The second set of memory channels 106b includes third memory channels 106b1 and fourth memory channels 106b2 (FIG. 2C). The third memory channels 106b1 and the fourth memory channels 106b2 are interleaved in a single column formed on the host IC 107 (FIG. 2C). For example, the host circuitry 104 includes two sets of memory channels arranged in a 1×2 array. Each of the memory channels includes pins and traces that are used to transmit and/or receive data between the host circuitry 104 and the memory circuitry 110. Each of the memory channels may be configured to receive/transmit data ranging in size from a bit of data to multiple bytes of data.

The first set of memory channels 106a are coupled to a first set of host I/O pins (herein described as “host pins”) 108a in a fan-out-package 109 of the host circuitry 104 (FIG. 2B). An I/O pin (such as the host pins) may be connected to the substrate, an electrical connection, and/or a physical connection. For example, the host pins are used to mount the host circuitry 104 to the PCB 102. The host pins are mounted to corresponding pins on the PCB 102. The second set of memory channels 106b are coupled to a second set of host pins 108b formed in the fan-out-package 109 of the host circuitry 104 (FIG. 2C). The fan-out-package 109 includes layers of traces that couple each of the sets of memory channels to a corresponding set of host pins. For example, the first set of memory channels 106a are coupled to the first set of host pins 108a using first host traces 128a formed in a first layer of the fan-out-package 109 of the host circuitry 104 (FIG. 2B). The second set of memory channels 106b is coupled to the second set of host pins 108b using second host traces 128b formed in a second layer of the fan-out-package (FIG. 2C). In one or more examples, the first set of host pins 108a includes first host pins 108a1 that are coupled the first memory channels 106a1 and second host pins 108a2 that are coupled the second memory channels 106a2 (FIG. 2B). The second set of host pins 108b includes third host pins 108b1 that are coupled the third memory channels 106b1 and fourth host pins 108b2 that are coupled the fourth memory channels 106b2 (FIG. 2C). The host pins 108a1-108b2 may each include one or more pins corresponding on how much data (and therefore) the amount of traces and pin included in each of the memory channels.

The first set of host pins 108a and the second set of host pins 108b are used to couple the memory channels to the memory circuitry 110. The memory circuitry 110 includes a first memory device 112a (FIG. 2B), a second memory device 112b (FIG. 2B), a third memory device 112c (FIG. 2C), and a fourth memory device 112d (FIG. 2C). Each memory device includes a set of memory chips. For example, the first memory device 112a includes a first set of memory chips 114a, the second memory device 112b includes a second set of memory chips 114b, the third memory device 112c includes a third set of memory chips 114c, and the fourth memory device 112d includes a fourth set of memory chips 114d. Each of the sets of memory chips 114a-114d include memory chips 113 arranged in columns within each of the memory devices 112a-112d along with the RCD circuitry 115 (FIGS. 2B-2C).

Each memory device includes a set of I/O pins that correspond to each of the memory chips 113 and the RCD circuitry 115. Each set of memory devices 112a-112d includes a set of I/O pins (herein defined as “memory pins”) that are configured to receive and/or provide data (output data) to the host circuitry 104 based on instructions/commands received by the RCD circuitry 115. An I/O pin (such as the memory pins) may be connected to the substrate, an electrical connection, and/or a physical connection. For example, the memory pins are used to mount the memory circuitry 110 to the PCB 102. For example, the memory pins are mounted to corresponding pins on the PCB 102. Stated otherwise, each set of memory pins includes a plurality of memory pins along with at least one RCD I/O pin 117 (herein described as “RCD pin(s) 117”). For example, the first memory device 112a includes a first set of memory pins 116a including first memory pins 116a1 coupled to the memory chips 113 and the RCD pin(s) 117 coupled to the RCD circuitry 115 of the first memory device 112a (FIG. 2B). The second memory device 112b includes a second set of memory pins 116b including second memory pins 116b1 coupled to the memory chips 113 and the RCD pin(s) 117 coupled to the RCD circuitry 115 of the second memory device 112b (FIG. 2B). The third memory device 112c includes a third set of memory pins 116c including third memory pins 116c1 coupled to the memory chips 113 and the RCD pin(s) 117 coupled to the RCD circuitry 115 of the third memory device 112c (FIG. 2C). The fourth memory device 112d includes a fourth set of memory pins 116d including fourth memory pins 116d1 coupled to the memory chips 113 and the RCD pin(s) 117 coupled to the RCD circuitry 115 of the fourth memory device 112d (FIG. 2C). As understood by those with ordinary skill in the art each first memory pin 116a1, second memory pin 116b2, third memory pin 116c1, and fourth memory pin 116d1 may represent one or more memory pins. In one or more examples, a command signal from by the host circuitry 104 will be provided to the RCD circuitry 115 via the RCD pin(s) 117 of each memory device. The command signal provided by the host circuitry 104, instructs the RCD circuitry 115 to cause data to be either read from or written to a memory chip 113 indicated by a memory chip address in the command signal from the host circuitry 104.

The host circuitry 104 is coupled to the memory circuitry 110 using layers of traces and vias formed in the PCB 102. Stated differently, the host pins are coupled to the memory pins using layers on traces and vias formed in the PCB 102. As noted above, each set of memory channels are coupled to a corresponding memory device. For example, the first memory channels 106a1 are coupled to the first memory device 112a, the second memory channels 106a2 are coupled to the second memory device 112b, the third memory channels 106b1 are coupled to the third memory device 112c, the fourth memory channels 106b2 (the fourth set of memory channels) are coupled to the fourth memory device 112d (FIGS. 2B-2C).

Additionally, because the first memory channels 106a1 and the second memory channels 106a2 are interleaved in the first set of memory channels 106a, the first set of memory channels 106a (i.e., the first and second sets of memory channels) are coupled to the first set of host pins 108a in the first layer of the fan-out-package 109 of the host circuitry 104. Because the third memory channels 106b1 and the fourth memory channels 106b2 are interleaved in the second set of memory channels 106b, the second set of memory channels 106b (i.e., the third and fourth sets of memory channels) are coupled to the second set of host pins 108b in the second layer of the fan-out-package 109 of the host circuitry 104. Therefore, the host circuitry 104 is coupled to the memory circuitry 110 by coupling the first set of host pins 108a to the first set of memory pins 116a and the second set of memory pins 116b. The second set of host pins 108b are coupled to the third set of memory pins 116c and the fourth set of memory pins 116d.

The first set of host pins 108a are coupled to the first set of memory pins 116a and the second set of memory pins 116b via the first memory traces 118a. The second set of host pins 108b are coupled to the third set of memory pins 116c and the fourth set of memory pins 116d using the second memory traces 118b. In one or more examples, the first memory traces 118a are formed in the first layer of the fan-out-package 109 and the second memory traces 118b are formed in the second layer of the fan-out-package 109 (or vice versa).

Referring to FIG. 2A, the first set of host pins 108a are coupled to the first memory traces 118a using first vias 120a. The second set of host pins 108b are coupled to the second memory traces 118b using second vias 120b. The first set of memory pins 116a are coupled to the first memory traces 118a using third vias 120c. The second set of memory pins 116b are coupled to the first memory traces 118a using fourth vias 120d. The third set of memory pins 116c are coupled to the second memory traces 118b using fifth vias 120e. The fourth set of memory pins 116d are coupled to the second traces 118d using sixth vias 120f.

Advantageously, by interleaving the memory channels in the host circuitry 104, only two layers of traces in both the fan-out-package and the PCB 102 are required to couple the host circuitry 104 to the memory circuitry while still using direct pin-to-pin connections. For example, if the 4 sets of memory channels were arranged in 2×2 arrays, complex routing of traces (such as traces having “L” shapes) and/or vias would be required in to couple the host circuitry 104 and the memory circuitry 110. On the other hand, if the memory channels were arranged as 1×4 arrays, 4 layers of traces would be required to couple the host circuitry 104 to the memory circuitry 110. Therefore, by interleaving the memory channels, the memory channels are arranged in a 1×2 array which reduces the required quantity of layers of traces while allowing for direct pin-to-pin connects (i.e., does not require complex routing). Therefore, the traces are relatively straight and short in length, which minimizes insertion loss and allows for improved signal integrity.

Although the sets of memory channels are described as including two different memory channels that are interleaved, any suitable quantity of memory different memory channels may be interleaved within a set of memory channels based on the dimensions of the host IC 107. Additionally, even though the sets of memory channels are included in a 1×4 array, any suitable 1×n array of sets of memory channels may be used, where n is an integer greater than or equal to 1. Furthermore, in one or more examples, more than one layer of traces may be used to couple a set of interleaved memory channels to a corresponding memory device. For example, one and one half layers of traces may be used to couple the first set of memory channels 106a (i.e., the first memory channels 106a1 and the second memory channels 106a2) to a respective one of the first memory device 112a and the second memory device 112b.

Referring to FIG. 2B, a first layer of the memory system 100 shows the first set of memory channels 106a coupled to the first memory device 112a and the second memory device 112b. As noted above the host IC 107 includes a first set of memory channels 106a and a second set of memory channels 106b. The first set of memory channels 106a includes first memory channels 106a1 and second memory channels 106a2 that are interleaved with each other. Stated otherwise, the first memory channels 106a1 are used to communicate with the first memory device 112a and the second memory channels 106a2 are used to communicate with the second memory device 112b.

The second set of memory channels 106b include third memory channels 106b1 and fourth memory channels 106b2 that are interleaved with each other. Stated otherwise, the third memory channels 106b1 are used to communicate with the third memory device 112c and the fourth memory channels 106b2 are used to communicate with the fourth memory device 112d in a second layer of the memory system 100 (FIG. 2C).

Each of the first memory channels 106a1 and the second memory channels 106a2 are coupled to the first set of host pins 108a in the fan-out-package 109 of the host circuitry 104. As noted above, the fan-out-package 109 includes layers of traces that couple each of the sets of memory channels to a corresponding set of host pins. For example, the first memory channels 106a1 and the second memory channels 106a2 are coupled to the first set of host pins 108a using the first memory traces 118a formed in a first layer of the fan-out-package 109. The first set of host pins 108a includes first host pins 108a1 that are coupled to the first memory channels 106a1 and second host pins 108a2 that are to coupled the second memory channels 106a2.

The first set of host pins 108a (and the second set of host pins 108b) are used to couple the memory channels of the host circuitry 104 to the memory circuitry 110. As noted above, each memory device includes a set of memory chips that are configured to receive and/or provide data (output data) to the memory channels of the host circuitry 104 based on instructions/commands received by the RCD circuitry 115. Each memory device includes a set of memory pins coupled to corresponding memory chips. Each set of memory pins includes a plurality of memory pins along with the RCD pin(s) 117. For example, the first memory device 112a includes a first set of memory pins 116a and the second memory device 112b includes a second set of memory pins 116b. The third memory device 112c and the fourth memory device 112d are omitted from FIG. 2B for illustrative purposes only.

The first set of memory pins 116a include first memory pins 116a1 coupled to the memory chips 113 and the RCD pin(s) 117 coupled to the RCD circuitry 115 of the first memory device 112a. The second memory device 112b includes a second set of memory pins 116b including second memory pins 116b1 coupled to the memory chips 113 and the RCD pin(s) 117 coupled to the RCD circuitry 115 of the second memory device 112b. In one or more examples, a command signal provided by the host circuitry 104 will be delivered to the RCD circuitry 115 via the RCD pin(s) of each memory device. The command signals provided by the host circuitry 104, instructs the RCD circuitry 115 to cause data to be either read from or written to a memory chip 113 indicated by a memory chip address in the command signal from the host circuitry 104.

In one or more examples, the first memory channels 106a1 are coupled to corresponding memory chips 113 and the corresponding RCD circuitry 115 of the first memory device 112a. The first host pins 108a1 are coupled to the first set of memory pins 116a of the first memory device 112a. The first host pins 108a1, which are coupled to corresponding first memory channels 106a1 via the first host traces 128a, are coupled to corresponding first memory pins 116a1 and a corresponding RCD pin(s) 117 of the first set of memory pins 116a via the first memory traces 118a.

In one or more examples, the RCD circuitry 115 of the first memory device 112a will receive a command from the host circuitry 104 at the RCD pin(s) 117. The RCD circuitry 115 of the first memory device 112a, based on the command received at the RCD pin(s) 117, will cause data from one or more of the memory chips 113 of the first memory device 112a to receive data from or output data to a corresponding first memory channel 106a1

The second memory channels 106a2 are coupled to corresponding memory chips 113 and the corresponding RCD circuitry 115 of the second memory device 112b. The second host pins 108a2 are coupled to the second set of memory pins 116b of the second memory device 112b. The second host pins 108a2, which are coupled to corresponding second memory channels 106a2 via the first host traces 128a, are coupled to corresponding second memory pins 116b1 and a corresponding RCD pin(s) 117 of the second set of memory pins 116b via the first memory traces 118a.

In one or more examples, the RCD circuitry 115 of the second memory device 112b will receive a command signal from the host circuitry 104 at the RCD pin(s) 117. The RCD circuitry 115 of the second memory device 112b, based on the command signal received at the RCD pin(s) 117, will cause data from one or more of the memory chips 113 of the second memory device 112b to read or write data to a corresponding second memory channel 106a2.

Referring to FIG. 2C, a second layer of the memory system 100 shows the second set of memory channels 106b coupled to the third memory device 112c and the fourth memory device 112d. The second set of memory channels 106b includes third memory channels 106b1 and fourth memory channels 106b2 that are interleaved with each other. Stated otherwise, the third memory channels 106b1 are used to communicate with the third memory device 112c and the fourth memory channels 106b2 are used to communicate with the fourth memory device 112d. The first memory device 112a, the second memory device 112b, the first set of memory channels 106a, and the second set of memory channels 106b are omitted from FIG. 2C for illustrative purposes only.

Each of the third memory channels 106b1 and the fourth memory channels 106b2 are coupled to the second set of host pins 108b in the fan-out-package 109 of the host circuitry 104. As noted above, the fan-out-package 109 includes layers of traces that couple each of the sets of memory channels to a corresponding set of host pins. For example, the third memory channels 106b1 and the fourth memory channels 106b2 are coupled to the second set of host pins 108b using the second memory traces 118b formed in the second layer of the fan-out-package. The second set of host pins 108b includes third host pins 108b1 that are coupled to the third memory channels 106b1 and fourth host pins 108b2 that are to coupled the fourth memory channels 106b2.

The second set of host pins 108b are used to couple third memory channels 106b1 and the fourth memory channels 106b2 to the memory circuitry 110. As noted above each memory device includes a set of memory pins that are configured to receive and/or provide data (output data) to the host circuitry 104 based on instructions/commands provided by the RCD circuitry 115. Each set of memory pins includes a plurality of memory pins along with the RCD pin(s) 117. For example, the third memory device 112c includes a third set of memory pins 116c and the fourth memory device 112d includes a fourth set of memory pins 116d.

The third set of memory pins 116c include the third memory pins 116c1 coupled to the memory chips 113 and RCD pin(s) 117 coupled to the RCD circuitry 115 of the third memory device 112c. The fourth memory device 112d includes a fourth set of memory pins 116d including the fourth memory pins 116d1 coupled to the memory chips 113 and the RCD pin(s) 117 coupled to the RCD circuitry 115 of the fourth memory device 112d. In one or more examples, a command signal provided by the host circuitry 104 will be delivered to the RCD circuitry 115 via the RCD pin(s) 117 of each memory device. The command signal provided by the host, instructs the RCD circuitry 115 to cause data to be either read from or written to a memory chip 113 indicated by a memory chip address in the command from the host circuitry 104.

In one or more examples, the third memory channels 106b1 are coupled to corresponding memory chips 113 and the corresponding RCD circuitry 115 of the third memory device 112c. The third host pins 108b1 are coupled to the third set of memory pins 116c of the third memory device 112c. The third host pins 108b1, which are coupled to corresponding third memory channels 106b1 via the second memory traces 118b, are coupled to corresponding third memory pins 116c1 and corresponding RCD pin(s) 117 of the third set of memory pins 116c via the second memory traces 118b.

In one or more examples, the RCD circuitry 115 of the third memory device 112c will receive a command from the host circuitry 104 at the RCD pin(s) 117. The RCD circuitry 115 of the third memory device 112c, based on the command received at the RCD pin(s) 117, will cause data from one or more of the memory chips 113 of the third memory device 112c to read or output data to a corresponding third memory channel 106b1.

The fourth memory channels 106b2 are coupled to corresponding memory chips 113 and the corresponding RCD circuitry 115 of the fourth memory device 112d. The fourth host pins 108b2 are coupled to the fourth set of memory pins 116d of the fourth memory device 112d. The fourth host pins 108b2, which are coupled to corresponding fourth memory channels 106b2 via the second memory traces 118b, are coupled to corresponding fourth memory pins 116d1 and corresponding RCD pin(s) 117 of the fourth set of memory pins 116d via the second memory traces 118b.

In one or more examples, the RCD circuitry 115 of the fourth memory device 112d will receive a command from the host circuitry 104 at the RCD pin(s) 117. The RCD circuitry 115 of the fourth memory device 112d, based on the command signal received at the RCD pin(s) 117, will cause data from one or more of the memory chips 113 of the fourth memory device 112d to read or output data to a corresponding fourth memory channel 106b2.

Advantageously, as noted above, by interleaving the memory channels in the host circuitry 104, only two layers of traces are required to couple the host circuitry 104 to the memory circuitry 110 while still using direct pin-to-pin connections. On the other hand, if the sets of memory channels were arranged as 1×4 arrays, 4 layers of traces would be required to couple the host circuitry 104 to the memory circuitry 110. Also as noted above, although the set of memory channels are described as including two different memory channels that are interleaved sets, any suitable quantity of memory different memory channels may be interleaved within a set of memory channels based on the dimensions of the host IC 107.

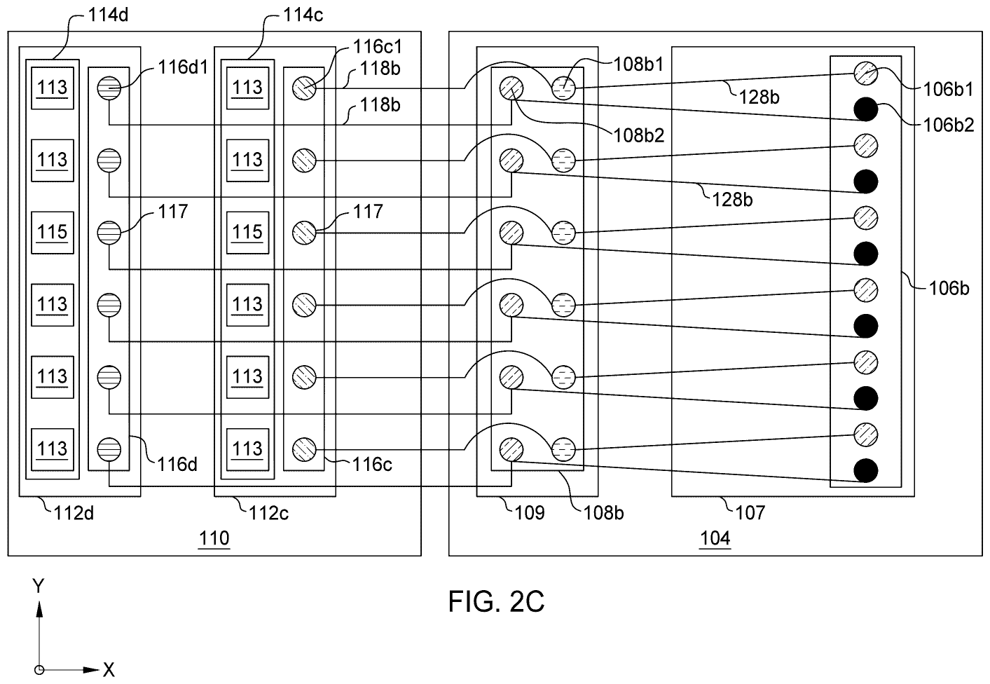

Additionally, the arrangement of the memory channels within the host circuitry 104 is flexible. In one or more examples, the set memory channels from an array in a in a trapezoidal shape to make better use of the space within the host circuitry 104. This is explained in more detail in FIG. 3 below.

FIG. 3 illustrates an abstract schematic view of a host IC 107 of the memory system 100 in the x-y plane according to one or more examples. As noted above, more than two different types of memory channels can be interleaved into a set of memory channels to improve the floorplan (i.e., better utilize space within the host circuitry 104). In one or more examples, at least one third memory channel 106b1 and fourth memory channel 106b2 can be interleaved in the first set of memory channels 106a. Furthermore, at least one third host pin 108b1 and at least one fourth host pin 108b2 may be further included in the first set of host pins 108a. The at least one third host pin 108b1 is coupled to a corresponding third memory channel 106b1. The at least one fourth host pin 108b2 is coupled to a corresponding fourth memory channel 106b2. Therefore, the first set of memory channels 106a is longer in length (i.e., includes more memory channels) than the second set of memory channels 106b. Furthermore, as noted above, the host IC 107 (i.e., the host circuitry 104) may include a third set of memory channels 308 that further includes fifth memory channels 306a interleaved with sixth memory channels 306b. In the same manner described above at least one fifth memory channel 306a and sixth memory channel 306b may be interleaved into the second set of memory channels 106b. Therefore, the second set of memory channels 106b is longer in length (includes more memory channels) than the third set of memory channels 308. Stated otherwise, the sets of memory channels decrease in length from the first set of memory channels 106a to the third set of memory channels 308. In the same manner described above the three sets of memory channels are arranged in an 1×n array (i.e., a 1×3 array) that allows direct pin-to-pin communication between the host circuitry 104 and the memory circuitry 110 using a reduced quantity of layers in the PCB 102. Furthermore, the trapezoidal shaped array allows for better use of the die corner of the host circuitry 104 and provides more neighboring area, allowing more room for functional circuitry within the host circuitry 104.

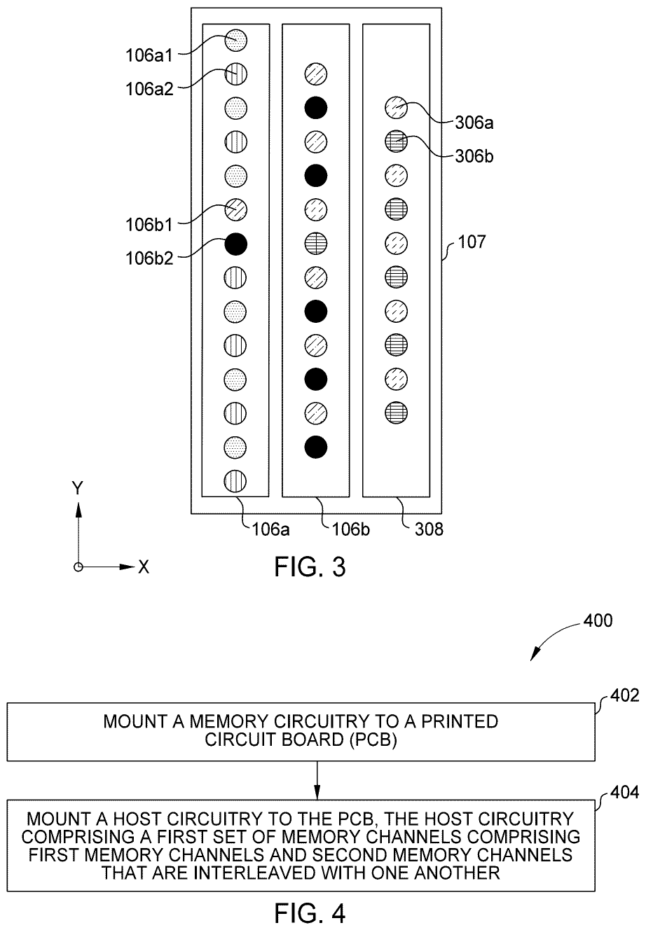

FIG. 4 illustrates a flow diagram of a method 400 for forming a memory system 100.

At operation 402 of method 400, the memory circuitry 110 is mounted to the PCB 102. The memory circuitry 110 includes a first memory device 112a and a second memory device 112b. The first memory device 112a includes a first set of memory chips 114a and a first set of memory pins 116a. The first set of memory pins 116a includes first memory pins 116a1 that are coupled to the first set of memory chips 114a. The second memory device 112b includes a second set of memory chips 114b and a second set of memory pins 16b. The second send of memory chips 114b are coupled to the second set of memory chips 114b. The first set of memory chips 114a and the second set of memory chips 114b are mounted to corresponding pins of the PCB 102.

At operation 404 of method 400, a host circuitry 104 is mounted to the PCB 102. The host circuitry 104 includes a first set of memory channels 106a. The first set of memory channels 106a includes the first memory channels 106a1 and the second set of memory channel 106a2 that are interleaved with one another. The host circuitry 104 further includes a first set of host pins 108a that include first host pins 108a1 and second host pins 108a2. The first host pins 108a1 are coupled to the first memory channels 106a1 and the second host pins 108a2 are coupled to the second memory channels.

The host circuitry further includes first memory traces 118a formed in a first layer of a fan-out-package 109. The first memory traces 118a couple the first hoist pins 108a1 to the first memory pins 116a1 and the second host pins 108a2 to the second memory pins 116b1.

While the foregoing is directed to specific examples, other and further examples may be devised without departing from the basic scope thereof, and the scope thereof is determined by the claims that follow

What is claimed is:

1. A memory system comprising:
a printed circuit board (PCB);
a memory circuitry mounted to the PCB comprising:
a first memory device comprising a first set of memory chips and a first set of memory pins comprising first memory pins coupled to the first set of memory chips; and
a second memory device comprising a second set of memory chips and a second set of memory pins comprising second memory pins coupled to the second set of memory chips, wherein the first set of memory pins and the second set of memory pins are mounted to corresponding pins of the PCB; and
a host circuitry mounted to the PCB and coupled to the memory circuitry, the host circuitry comprising:
a first set of memory channels comprising first memory channels and second memory channels that are interleaved with one another;
a first set of host pins comprising first host pins that are coupled to the first memory channels and second host pins that are coupled to the second memory channels; and
first memory traces formed in a first layer of a fan-out package, the first memory traces coupling the first host pins to the first memory pins and the second host pins to the second memory pins.

2. The memory system of claim 1, wherein the host circuitry further comprises:
a second set of memory channels comprising third memory channels and fourth memory channels that are interleaved with one another; and
a second set of host pins comprising third host pins that are coupled to the third memory channels and fourth host pins that are coupled to the fourth memory channels.

3. The memory system of claim 2, wherein the memory circuitry further comprises:
a third memory device comprising a third set of memory chips and a third set of memory pins comprising third memory pins coupled to the third set of memory chips; and
a fourth memory device comprising a fourth set of memory chips and a fourth set of memory pins comprising fourth memory pins coupled to the fourth set of memory chips.

4. The memory system of claim 3, further comprising second memory traces formed in a second layer of the fan-out package, the second memory traces coupling the third host pins to the third memory pins and the fourth host pins to the fourth memory pins.

5. The memory system of claim 1, wherein the first set of memory channels further includes at least one third memory channel and at least one fourth memory channel interleaved with the first memory channels and the second memory channels.

6. The memory system of claim 5, wherein the first set of host pins includes at least one third host pin coupled to the at least one third memory channel, and at least one fourth host pin coupled to the at least one fourth memory channel.

7. The memory system of claim 5, wherein the second set of memory channels further includes at least one fifth memory channel and at least one sixth memory channel interleaved with the third memory channels and the fourth memory channels.

8. The memory system of claim 1, wherein the first memory device and the second memory device each comprise a registered clock driver (RCD) circuitry.

9. The memory system of claim 8, wherein the first set of memory pins comprise RCD pins coupled to the RCD circuitry of the first memory device, and the second set of memory pins comprise RCD pins coupled to the RCD circuitry of the second memory device.

10. A host circuitry for coupling to a memory circuitry, the host circuitry comprising:
a first set of memory channels comprising first memory channels and second memory channels that are interleaved with one another; and
a second set of memory channels comprising third memory channels and fourth memory channels that are interleaved with one another.

11. The host circuitry of claim 10, wherein the memory circuitry further comprises:
a first memory device comprising a first set of memory chips and a first set of memory pins comprising first memory pins coupled to the first set of memory chips; and
a second memory device comprising a second set of memory chips and a second set of memory pins comprising second memory pins coupled to the second set of memory chips.

12. The host circuitry of claim 11, wherein the host circuitry further comprises:
a first set of host pins comprising first host pins that are coupled to the first memory channels and second host pins that are coupled to the second memory channels;
first memory traces formed in a first layer of a fan-out package, the first memory traces coupling the first host pins to the first memory pins and the second host pins to the second memory pins; and
a second set of host pins comprising third host pins that are coupled to the third memory channels and fourth host pins that are coupled to the fourth memory channels.

13. The host circuitry of claim 12, wherein the memory circuitry further comprises:
a third memory device comprising a third set of memory chips and a third set of memory pins comprising third memory pins coupled to the third set of memory chips; and
a fourth memory device comprising a fourth set of memory chips and a fourth set of memory pins comprising fourth memory pins coupled to the fourth set of memory chips.

14. The host circuitry of claim 13, further comprising second memory traces formed in a second layer of the fan-out package, the second memory traces coupling the third host pins to the third memory pins and the fourth host pins to the fourth memory pins.

15. The host circuitry of claim 10, wherein the first set of memory channels further includes at least one third memory channel and at least one fourth memory channel interleaved with the first memory channels and the second memory channels.

16. The host circuitry of claim 15, wherein the first set of host pins includes at least one third host pin coupled to the at least one third memory channel, and at least one fourth host pin coupled to the at least one fourth memory channel.

17. The host circuitry of claim 16, wherein the second set of memory channels further includes at least one fifth memory channel and at least one sixth memory channel interleaved with the third memory channels and the fourth memory channels.

18. The host circuitry of claim 11, wherein the first memory device and the second memory device each comprise a registered clock driver (RCD) circuitry.

19. The host circuitry of claim 18, wherein the first set of memory pins comprise RCD pins coupled to the RCD circuitry of the first memory device, and the second set of memory pins comprise RCD pins coupled to the RCD circuitry of the second memory device.

20. A method comprising:
mounting a memory circuitry to a PCB, the memory circuitry comprising:
a first memory device comprising a first set of memory chips and a first set of memory pins comprising first memory pins coupled to the first set of memory chips; and
a second memory device comprising a second set of memory chips and a second set of memory pins comprising second memory pins coupled to the second set of memory chips, wherein the first set of memory pins and the second set of memory pins are mounted to corresponding pins of the PCB; and
mounting a host circuitry to the PCB, the host circuitry comprising:
a first set of memory channels comprising first memory channels and second memory channels that are interleaved with one another;
a first set of host pins comprising first host pins that are coupled to the first memory channels and second host pins that are coupled to the second memory channels; and
first memory traces formed in a first layer of a fan-out package, the first memory traces coupling the first host pins to the first memory pins and the second host pins to the second memory pins.
